(19) United States
(12) Patent Application Publication
(10) Pub. No.: US 2016/0241255 A1
(43) Pub. Date: Aug. 18, 2016

(54) SEMICONDUCTOR DEVICE, ELECTRONIC COMPONENT, AND ELECTRONIC DEVICE

(71) Applicant: Semiconductor Energy Laboratory Co., Ltd., Atsugi-shi (JP)

(72) Inventor: Kei TAKAHASHI, Isehara (JP)

(73) Assignee: Semiconductor Energy Laboratory Co., Ltd.

(21) Appl. No.: 15/041,532

(22) Filed: Feb. 11, 2016

(30) Foreign Application Priority Data
Feb. 17, 2015 (JP) 2015-028351

(51) Int. Cl. H03M 1/68; G09G 3/20; H03K 5/13

(52) U.S. Cl. CPC H03M 1/68; H03K 5/13; G09G 3/2003; H03K 2005/00286

(57) ABSTRACT

A semiconductor device with a novel structure. An upper-bit grayscale voltage and a lower-bit grayscale voltage are separately produced, and then the grayscale voltages are converted into currents and the currents are synthesized. The obtained current is converted into a voltage, and thus an intended grayscale voltage is obtained. The upper-bit grayscale voltage and the lower-bit grayscale voltage are generated using respective D/A converter circuits each including a resistor string circuit and a pass transistor logic. The increase in the number of transistors supplied with high voltage, which occurs along with the increase in the number of digital signal bits, is prevented. Thus, the increase in parasitic capacitance can be suppressed, and a smaller circuit area and higher response speed are obtained.

### BACKGROUND OF THE INVENTION

1. Field of the Invention

One embodiment of the present invention relates to a semiconductor device, an electronic component, and an electronic device.

Note that one embodiment of the present invention is not limited to the above technical field. The technical field of the invention disclosed in this specification and the like relates to an object, a method, or a manufacturing method. In addition, one embodiment of the present invention relates to a process, a machine, manufacture, or a composition of matter. Specific examples of the technical field of one embodiment of the present invention disclosed in this specification include a semiconductor device, a display device, a light-emitting device, a power storage device, a memory device, a method for driving any of them, and a method for manufacturing any of them.

In this specification and the like, a semiconductor device refers to an element, a circuit, a device, or the like that can function by utilizing semiconductor characteristics. An example of the semiconductor device is a semiconductor element such as a transistor or a diode. Another example of the semiconductor device is a circuit including a semiconductor element. Another example of the semiconductor device is a device provided with a circuit including a semiconductor element.

2. Description of the Related Art

There has been a trend toward higher performance (e.g., multiple gray levels and higher definition) of display devices. To meet the demand for higher performance, an integrated circuit (IC, hereinafter also referred to as driver IC) is used as a driver circuit of a display device, particularly as a source driver.

A driver IC includes a grayscale voltage generator circuit for generating an analog signal supplied to pixels. The grayscale voltage generator circuit is a digital-to-analog (D/A) converter circuit, which generates an analog signal based on a digital signal.

As the D/A converter circuit, a resistor digital-to-analog converter (R-DAC), in which resistors are provided in series, is used in consideration of the requirement of high response speed. The number of switches in an R-DAC increases exponentially with the increase in the number of bits of digital signals; thus, the circuit area of a driver IC increases.

In view of the above, Patent Document 1 suggests a structure for obtaining an analog signal in such a manner that upper bits are converted by an R-DAC and lower bits are controlled by buffer amplifier offset. Patent Document 2 suggests a structure for obtaining an analog signal in such a manner that upper bits converted by an R-DAC and lower bits converted by a current DAC are synthesized by a buffer amplifier.

### REFERENCE

Patent Document 1: United States Patent Application Publication No. 2005/0140630

Patent Document 2: United States Patent Application Publication No. 2010/0156867

### SUMMARY OF THE INVENTION

As described above, there are a variety of structures of semiconductor devices functioning as grayscale voltage generator circuits. Each structure has advantages and disadvantages, and a structure appropriate for circumstances is selected. Thus, a proposal for a semiconductor device that has a novel structure and functions as a grayscale voltage generator circuit leads to higher degree of freedom of choice.

In view of the above, one embodiment of the present invention is to provide a novel semiconductor device that has a structure different from that of an existing semiconductor device functioning as a grayscale voltage generator circuit, a novel electronic component, a novel electronic device, or the like.

When a current DAC using switching of a switch is employed as in Patent Document 2, the switch is composed of a transistor with high withstand voltage. The increase in the number of switches due to the increase in the number of bits of digital signals causes a larger circuit area. Moreover, the increase in the number of switches due to a larger number of digital signal bits causes the increase in parasitic capacitance of an output portion, resulting in lower response speed.

In light of the above, an object of one embodiment of the present invention is to provide a semiconductor device or the like with a novel structure and a small circuit area. Another object of one embodiment of the present invention is to provide a semiconductor device or the like with a novel structure and high response speed.

Note that the objects of one embodiment of the present invention are not limited to the above. The objects described above do not preclude the existence of other objects. The other objects are objects that are not described above and will be described below. The other objects will be apparent from and can be derived from the description of the specification, the drawings, and the like by those skilled in the art. One embodiment of the present invention is to solve at least one of the above objects and the other objects.

One embodiment of the present invention is a semiconductor device including a first D/A converter circuit, a second D/A converter circuit, an interpolation circuit, and a voltage-current converter circuit. The first D/A converter circuit has a function of converting an upper (N-M)-bit digital signal among an N-bit digital signal into a first voltage (N is a natural number of 2 or more and M is a natural number less than N). The second D/A converter circuit has a function of converting a lower M-bit digital signal into a second voltage. The interpolation circuit has a function of generating a first current on the basis of the first voltage. The voltage-current converter circuit has a function of converting the second voltage into a second current. The interpolation circuit has a function of converting a current obtained by synthesis of the first current and the second current, into a voltage.

In the semiconductor device of one embodiment of the present invention, it is preferred that the first D/A converter circuit include a first resistor string circuit and a plurality of first switches, and that the second D/A converter circuit include a second resistor string circuit and a plurality of second switches.

In the semiconductor device of one embodiment of the present invention, the voltage-current converter circuit is preferably a transconductance amplifier.

In the semiconductor device of one embodiment of the present invention, the interpolation circuit is preferably a buffer amplifier.

One embodiment of the present invention can provide a novel semiconductor device, a novel electronic device, or the like.

One embodiment of the present invention can provide a semiconductor device or the like with a novel structure and a small circuit area. One embodiment of the present invention can provide a semiconductor device or the like with a novel structure and high response speed.

Note that the effects of one embodiment of the present invention are not limited to the above. The effects described above do not preclude the existence of other effects. The other effects are effects that are not described above and will be described below. The other effects will be apparent from and can be derived from the description of the specification, the drawings, and the like by those skilled in the art. One embodiment of the present invention is to have at least one of the above effects and the other effects. Accordingly, one embodiment of the present invention does not have the above effects in some cases.

### BRIEF DESCRIPTION OF THE DRAWINGS

In the accompanying drawings:

FIG. 1 is a circuit block diagram;

FIG. 2 illustrates a circuit;

FIG. 3 illustrates a circuit;

FIGS. 4A and 4B each illustrate a voltage to be generated;

FIG. 5 illustrates a circuit;

FIG. 6 illustrates a circuit;

FIG. 7 illustrates a circuit;

FIG. 8 illustrates a circuit;

FIG. 9 is a circuit block diagram;

FIGS. 10A and 10B each illustrate a circuit;

FIG. 11 is a schematic cross-sectional view;

FIG. 12A is a flowchart showing a fabrication process for an electronic component, and FIG. 12B is a schematic cross-sectional view of the electronic component;

FIGS. 13A and 13B each illustrate a display panel including an electronic component;

FIG. 14 illustrates a display module including a display panel; and

FIGS. 15A to 15E each illustrate an electronic device including an electronic component.

### DETAILED DESCRIPTION OF THE INVENTION

Embodiments will be hereinafter described with reference to the accompanying drawings. Note that the embodiments can be implemented with various modes, and it will be readily appreciated by those skilled in the art that modes and details can be changed in various ways without departing from the spirit and scope of the present invention. Thus, the present invention should not be interpreted as being limited to the following description of the embodiments.

In this specification and the like, ordinal numbers such as first, second, and third are used in order to avoid confusion among components. Thus, the terms do not limit the number or order of components. In this specification and the like, a “first” component in one embodiment can be referred to as a “second” component in other embodiments or claims. Furthermore, in this specification and the like, a “first” component in one embodiment can be omitted in other embodiments or claims.

The same elements or elements having similar functions, elements formed using the same material, elements formed at the same time, or the like in the drawings are sometimes denoted by the same reference numerals, and the description thereof is not repeated in some cases.

### Embodiment 1

In this embodiment, an example of a semiconductor device functioning as a grayscale voltage generator circuit will be described.

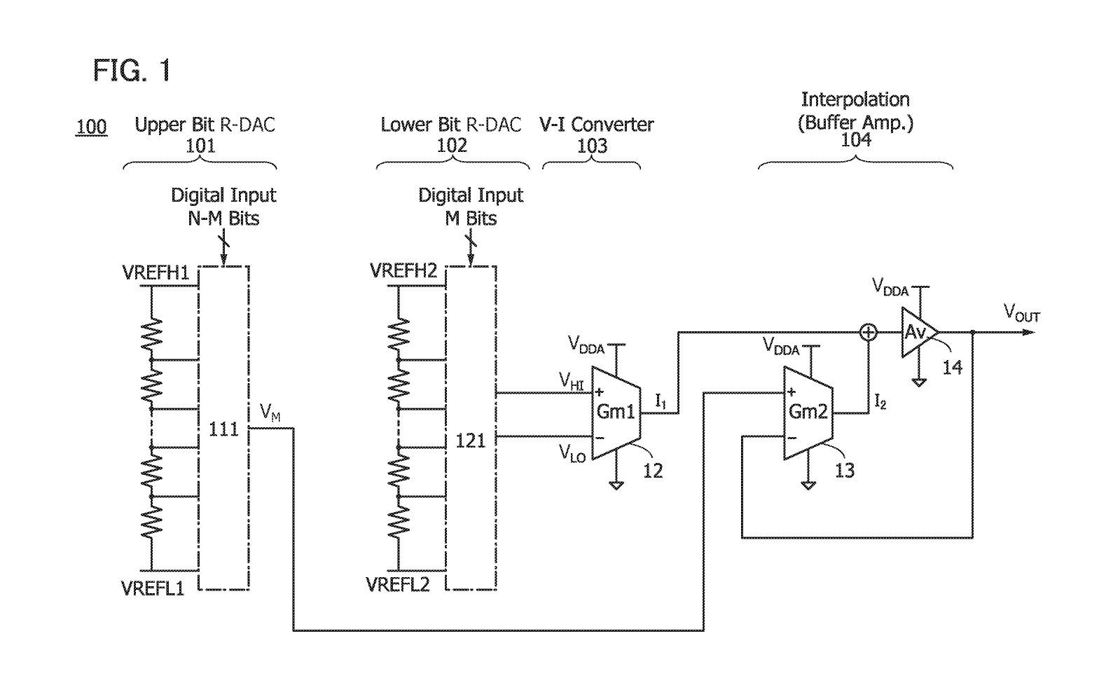

FIG. 1 is a schematic diagram showing circuit blocks of a semiconductor device 100.

The semiconductor device 100 includes a D/A converter circuit 101, a D/A converter circuit 102, a voltage-current converter circuit 103, and an interpolation circuit 104.

In the semiconductor device 100, a grayscale voltage corresponding to an upper bit of a digital signal is generated by the D/A converter circuit 101, and a grayscale voltage corresponding to a lower bit of the digital signal is generated by the D/A converter circuit 102. After the upper-bit grayscale voltage and the lower-bit grayscale voltage are generated separately, currents are generated in the voltage-current converter circuit 103 and the interpolation circuit 104 on the basis of the respective grayscale voltages. Then, these currents are synthesized in the interpolation circuit 104. The current obtained by synthesizing the upper-bit and lower-bit grayscale voltages is converted into a voltage. In such a manner, an intended grayscale voltage that is an analog signal converted from the digital signal is obtained.

Each of the grayscale voltages produced in the D/A converter circuits 101 and 102 is generated using a resistor string circuit and a pass transistor logic. The number of resistors can be decreased because the upper-bit and lower-bit digital signals are generated separately. In addition, the use of an R-DAC in both the D/A converter circuits 101 and 102 enables conversion with a short settling time and high response speed.

A voltage applied to transistors in the pass transistor logic included in the D/A converter circuit 102 can be lower than a voltage applied to a transistor provided in a current DAC that converts a lower-bit digital signal into a current, like the one shown in Patent Document 2. Accordingly, in a structure where a lower-bit grayscale voltage is generated by the pass transistor logic in the D/A converter circuit 102 and then converted into a current, the number of transistors to which high voltage is applied can be reduced. As the number of digital signals is larger, the number of transistors that require high withstand voltage because of high voltage being applied can be decreased.

The semiconductor device 100 can perform D/A conversion of a multi-bit digital signal with a smaller number of transistors requiring high withstand voltage, which are increased in number as the number of bits of digital signals is larger. As a result, it is possible to suppress the increase in parasitic capacitance, achieve a smaller circuit area, and increase the response speed.

Next, the circuits constituting the semiconductor device 100 will be described.

### D/A Converter Circuit 101

To the D/A converter circuit 101, an upper-bit digital signal is input, for example. The D/A converter circuit 101 has a function of outputting a voltage V_{M} in response to the upper-bit digital signal. A D/A converter circuit is sometimes referred to as a D/A converter or simply as a circuit.

Given that an original digital signal is an N-bit signal (N is a natural number of 2 or more), the upper-bit digital signal can be represented as an (N-M)-bit signal (M is a natural number less than N) and the lower-bit digital signal can be represented as an M-bit signal.

For example, the D/A converter circuit 101 is preferably composed of an R-DAC, which has a resistor string circuit including a plurality of resistors and a pass transistor logic. An R-DAC has a short settling time and high response speed and thus is particularly suitable for a high-definition display device with multiple gray levels.

The resistor string circuit is supplied with voltages VREFH1 and VREFL1 (VREFH1>VREFL1) and generates a plurality of voltages. A resistor string circuit is sometimes referred to as a voltage generator circuit because of its function of generating a plurality of voltages.

A pass transistor logic 111 includes a plurality of switches. The on/off state of each switch is switched in accordance with an upper-bit digital signal. The pass transistor logic 111 has a function of selecting an intended voltage V_{M} by switching of the switches and outputting the voltage V_{M}. The switch can be composed of a transistor.

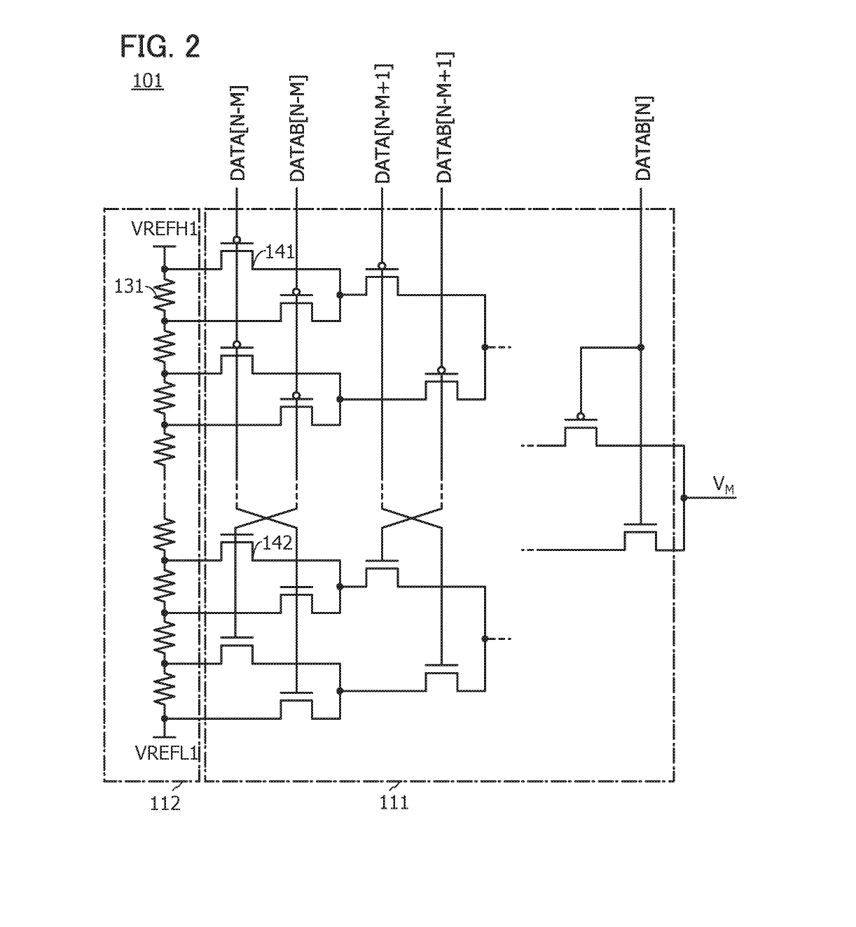

FIG. 2 is a more detailed circuit diagram of the D/A converter circuit 101. In FIG. 2, the D/A converter circuit 101 includes the pass transistor logic 111 and a voltage generator circuit 112 that is a resistor string circuit. The voltage generator circuit 112 includes a plurality of resistors 131. The pass transistor logic 111 includes a p-channel transistor 141 and an n-channel transistor 142. The transistors 141 and 142 function as switches, and their on/off states are controlled with upper-bit digital signals DATA[N-M] to DATA[N] and digital signals DATAB[N-M] to DATAB[N], the inverted signals of these upper-bit digital signals.

The voltage V_{M} output from the pass transistor logic 111 is an analog voltage corresponding to an upper-bit digital signal. The voltage V_{M} corresponds to a voltage for performing coarse interpolation by the interpolation circuit 104 in a subsequent stage.

### D/A Converter Circuit 102

To the D/A converter circuit 102, a lower-bit digital signal is input, for example. The D/A converter circuit 102 has a function of outputting voltages V_{HI} and V_{LO} in response to the lower-bit digital signal.

For example, the D/A converter circuit 102 is preferably composed of an R-DAC, which has a resistor string circuit including a plurality of resistors and a pass transistor logic. As described above, an R-DAC is particularly suitable for a high-definition display device with multiple gray levels.

The resistor string circuit is supplied with voltages VREFH2 and VREFL2 (VREFH2>VREFL2) and generates a plurality of voltages.

A pass transistor logic 121 includes a plurality of switches. The on/off state of each switch is controlled in accordance with an upper-bit digital signal. The pass transistor logic 121 has a function of selecting an intended voltage V_{HI} by switching of the switches and outputting the voltage V_{HI}. The voltage V_{LO} is any voltage serving as a reference, and for example, the voltage VREFL2 is output as the voltage V_{LO}.

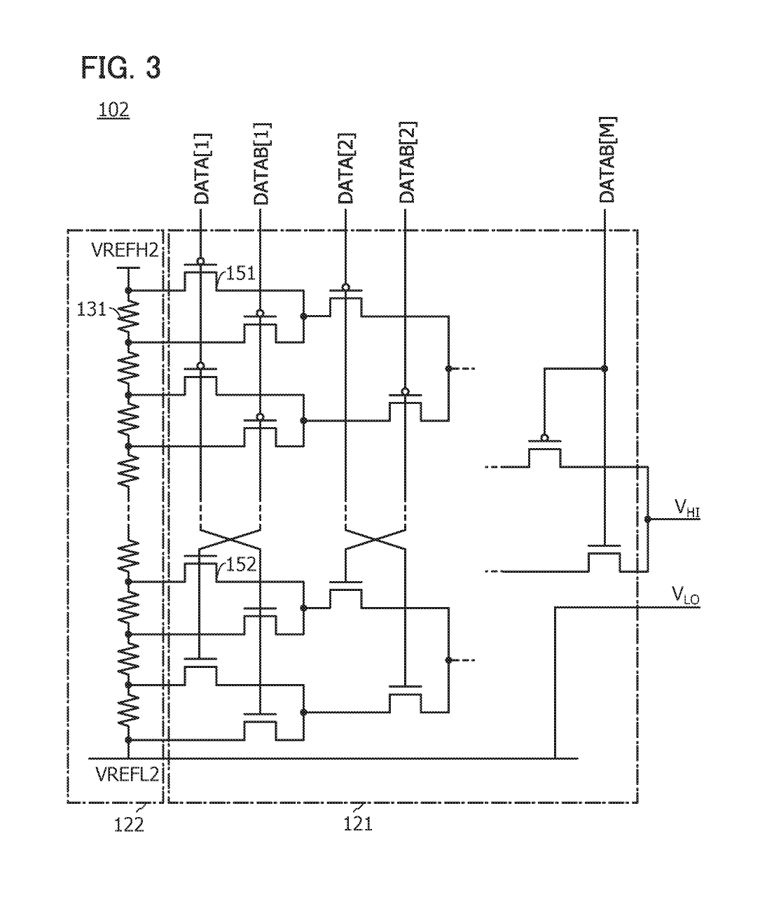

FIG. 3 is a more detailed circuit diagram of the D/A converter circuit 102. In FIG. 3, the D/A converter circuit 102 includes the pass transistor logic 121 and a voltage generator circuit 122 that is a resistor string circuit. The voltage generator circuit 122 includes a plurality of resistors 131. The pass transistor logic 121 includes a p-channel transistor 151 and an n-channel transistor 152. The transistors 151 and 152 function as switches, and their on/off states are controlled with lower-bit digital signals DATA[1] to DATA[M] and digital signals DATAB[1] to DATAB[M], the inverted signals of these lower-bit digital signals.

The voltage V_{HI} output from the pass transistor logic 121 is an analog voltage corresponding to a lower-bit digital signal. The voltage V_{HI} corresponds to a voltage for performing fine interpolation by the interpolation circuit 104 in the subsequent stage. In other words, the pass transistor logic 121 outputs a voltage ΔV (the difference between the voltage V_{HI} and the voltage V_{LO}) so that the interpolation circuit 104 in the subsequent stage can perform fine interpolation.

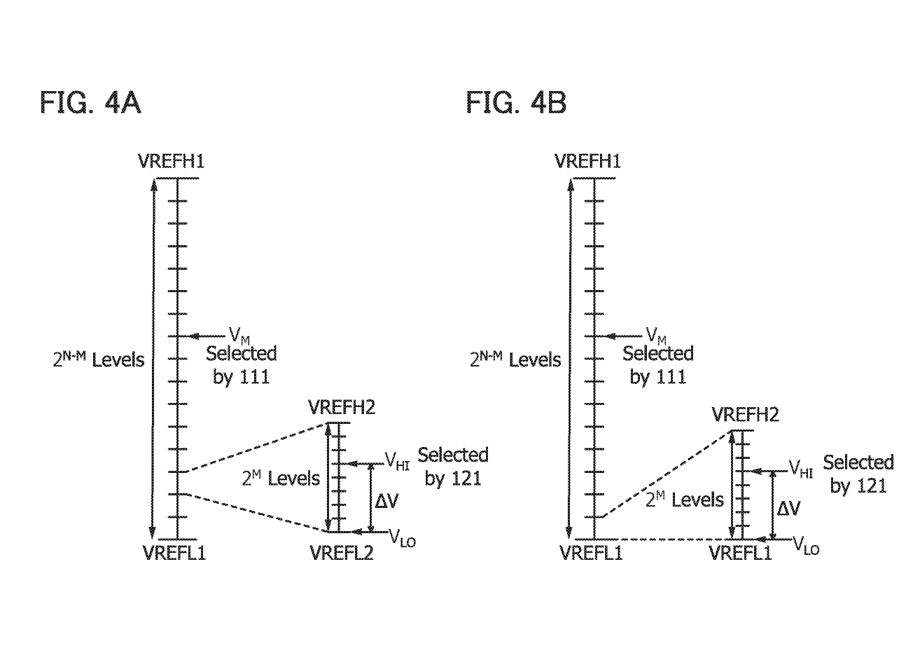

Using FIGS. 4A and 4B, the description is made on the magnitude relation between the voltages VREFH1 and VREFL1 applied to the voltage generator circuit 112 in the D/A converter circuit 101 and the voltages VREFH2 and VREFL2 applied to the voltage generator circuit 122 in the D/A converter circuit 102.

The voltage generator circuit 112 generates a plurality of voltage levels with the use of the plurality of resistors 131. For example, as illustrated in FIG. 4A, in the voltage generator circuit 112 supplied with upper (N-M)bits, a voltage between the voltages VREFH1 and VREFL1 is divided into 2^{N-M} levels and one of the voltages is selected by the pass transistor logic 111 and used as the voltage V_{M}.

Like the voltage generator circuit 112, the voltage generator circuit 122 generates a plurality of voltage levels with the use of the plurality of resistors 131. For example, as illustrated in FIG. 4A, in the voltage generator circuit 122 supplied with lower M bits, a voltage between the voltages VREFH2 and VREFL2 is divided into 2^{M} levels and one of the voltages is selected by the pass transistor logic 121 and used as the voltage V_{HI}. As described above, the voltage V_{LO} is the voltage VREFL2, for example. As shown in FIG. 4A, the voltage ΔV is the difference between the voltage V_{HI} and the voltage V_{LO}.

In the structure of this embodiment, the difference between the voltages VREFH2 and VREFL2 corresponds to a voltage corresponding to a section divided as one level by the voltage generator circuit 112. For example, given that the voltage VREFH1 is 8.5 V, the voltage VREFL1 is 0.5 V, and the upper bits are 7 bits, a voltage corresponding to a section divided as one level by the voltage generator circuit 112 is 62.5 mV. In this case, when the voltage VREFL2 is 1.25 V and the lower bits are 5 bits, the voltage VREFH2 is 1.25 V+62.5 mV.

As described above, with the structure of this embodiment, a voltage between the voltages VREFH2 and VREFL2 can be significantly lower than a voltage between the voltages VREFH1 and VREFL1. Thus, a voltage applied to the pass transistor logic 121 can be decreased, whereby the number of transistors to which high voltage is applied can be reduced. As the number of digital signals is larger, the number of transistors that require high withstand voltage because of high voltage being applied can be decreased.

Note that setting the voltage VREFL2 higher than the voltage VREFL1 allows the voltage-current converter circuit 103 and the interpolation circuit 104 in subsequent stages to operate stably. Moreover, setting the voltage VREFL1 higher than a potential supplied as a low power supply potential to the voltage-current converter circuit 103 and the interpolation circuit 104 (e.g., a ground potential) allows the voltage-current converter circuit 103 and the interpolation circuit 104 in the subsequent stages to operate stably.

In FIG. 4A, the voltage VREFL1 and the voltage VREFL2 may be the same voltage. In this case, the voltage VREFL1 can be supplied as shown in FIG. 4B, resulting in the reduction in the number of levels of voltage supplied to the semiconductor device 100.

### Voltage-Current Converter Circuit 103

To the voltage-current converter circuit 103, the voltages V_{HI} and V_{LO} are input, for example. The voltage-current converter circuit 103 has a function of outputting a current I₁ in response to the voltages V_{HI} and V_{LO}. A voltage-current converter circuit is sometimes referred to as a V/I converter or simply as a circuit.

The voltage-current converter circuit 103 includes a transconductance amplifier (Gm amplifier) 12 (shown as Gm1 in FIG. 1). A voltage V_{DDA} is applied to the transconductance amplifier 12.

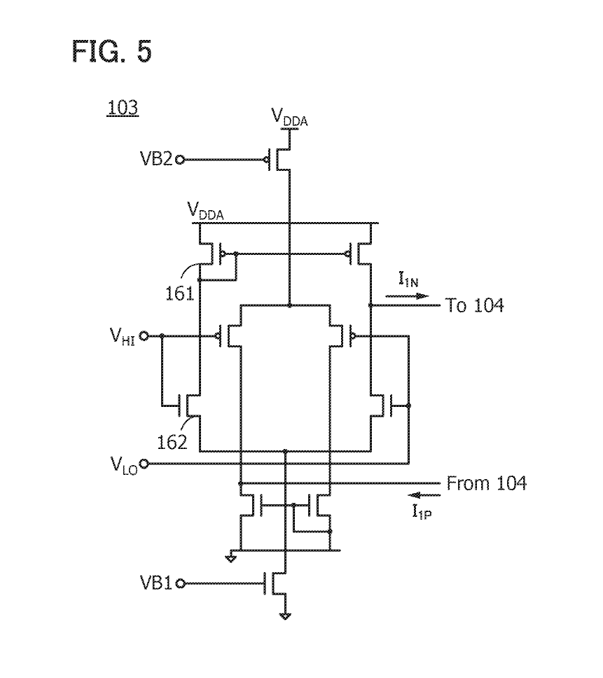

FIG. 5 shows a more detailed circuit diagram of the voltage-current converter circuit 103. In FIG. 5, the voltage-current converter circuit 103 has a configuration of a differential amplifier output circuit. The voltage-current converter circuit 103 includes a p-channel transistor 161 and an n-channel transistor 162. Bias voltages VB1 and VB2 make a constant current flow through the transistors 161 and 162, and the transistors 161 and 162 change currents I_{IN} and I_{IP} flowing between the interpolation circuit 104 and the transistors 161 and 162 in accordance with the difference between the voltages V_{HI} and V_{LO} (i.e., the voltage ΔV).

The currents I_{IN} and I_{IP} that correspond to the aforementioned current I₁ depend on the voltages V_{HI} and V_{LO}. The currents I_{IN} and I_{IP} correspond to currents for performing coarse interpolation by the interpolation circuit 104 in the subsequent stage.

### Interpolation Circuit 104

To the interpolation circuit 104, the voltage V_{M} and the current I₁ are input, for example. The interpolation circuit 104 has a function of outputting a voltage V_{OUT} in response to the voltage V_{M} and the current I₁. The interpolation circuit 104 may be referred to as a buffer amplifier or simply as a circuit.

For example, the interpolation circuit 104 includes a transconductance amplifier 13 (shown as Gm2 in FIG. 1) and a current-voltage converter circuit 14 (shown as Av in FIG. 1). The voltage V_{DDA} is applied to the transconductance amplifier 13 and the current-voltage converter circuit 14.

The transconductance amplifier 13 has a function of outputting a current I₂ in accordance with the voltages V_{M} and V_{OUT}. The current-voltage converter circuit 14 has a function of converting a current obtained by synthesis of the current I₁ and the current I₂ into the voltage V_{OUT} and outputting the voltage V_{OUT}.

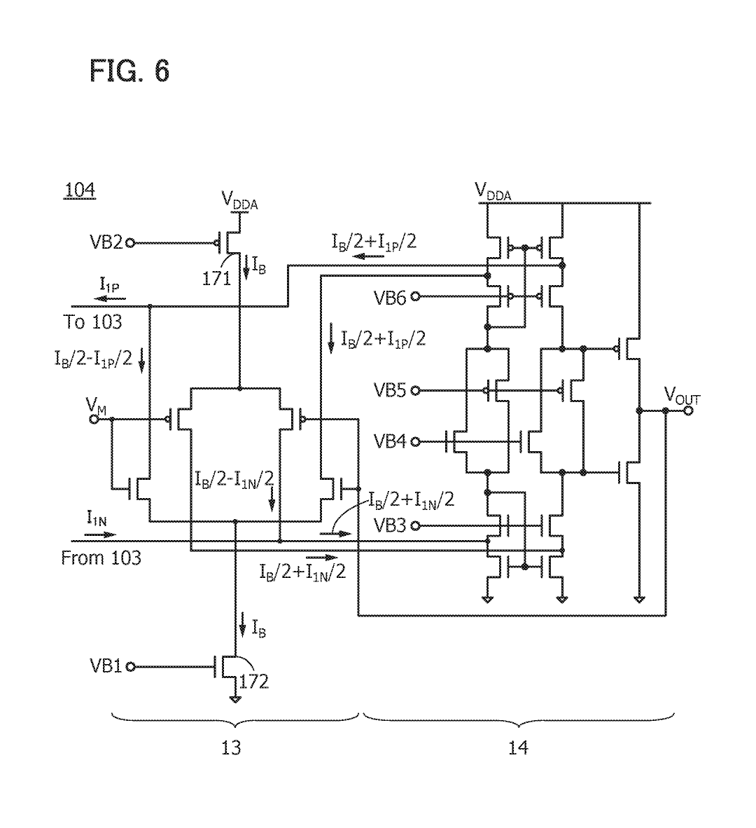

FIG. 6 illustrates a more detailed circuit diagram of the interpolation circuit 104. In FIG. 6, the interpolation circuit 104 includes the transconductance amplifier 13 and the current-voltage converter circuit 14. The transconductance amplifier 13 and the current-voltage converter circuit 14 each include a p-channel transistor 171 and an n-channel transistor 172.

In the transconductance amplifier 13, a constant current I_{B} flows by supplying the bias voltages VB1 and VB2 to the transistors 171 and 172. In the transconductance amplifier 13, a current I_{B}/2+I_{IP}/2 and a current I_{B}/2+I_{IN}/2 (that correspond to the current I₂ flowing between the transconductance amplifier 13 and the current-voltage converter circuit 14) are changed depending on the difference between the voltages V_{M} and V_{OUT}. In FIG. 6, the currents flowing between the circuits are indicated using arrows.

In the current-voltage converter circuit 14, a constant current flows by supplying bias voltages VB3 to VB6 to the transistors 171 and 172, and the voltage V_{OUT} corresponding to currents I_{B}/2±I_{IP}/2 and currents I_{B}/2±I_{IP}/2 is output.

The currents I_{B}/2±I_{IP}/2 and the currents I_{B}/2±I_{IN}/2 that correspond to the aforementioned current I₂ depend on the voltage V_{M}. The currents I_{B}/2±I_{IP}/2 and the currents I_{B}/2±I_{IN}/2 correspond to currents used for fine interpolation. The current-voltage converter circuit 14 can produce the voltage V_{OUT} serving as a grayscale voltage that is an analog voltage corresponding to the original digital signal, with the use of the currents I_{B}/2+I_{IP}/2 and I_{B}/2+I_{IN}/2, which are obtained by synthesizing the above currents I_{IN} and I_{IP} for coarse interpolation and the currents I_{B}/2±I_{IP}/2 and I_{B}/2±I_{IN}/2. In other words, the voltage V_{OUT} is a voltage V_{M}+ΔV, the addition of the voltage V_{M} and the voltage ΔV.

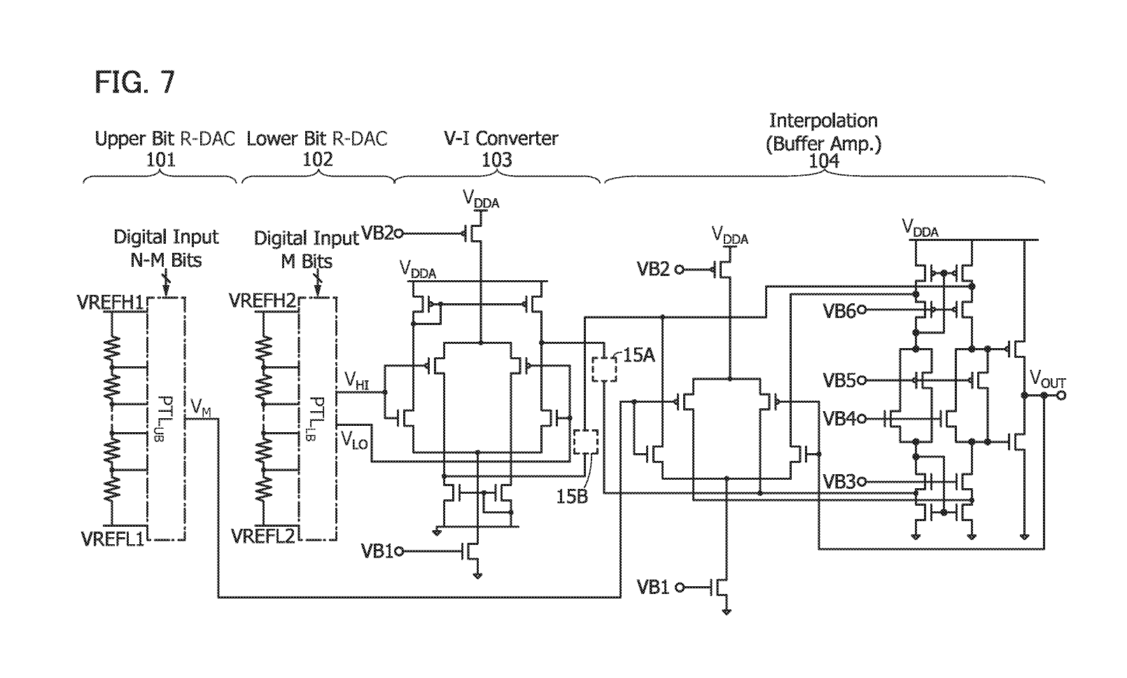

FIG. 7 is a circuit diagram showing a combination of the D/A converter circuit 101, the D/A converter circuit 102, the voltage-current converter circuit 103, and the interpolation circuit 104 included in the semiconductor device 100 described above. As illustrated in FIG. 7, a buffer circuit is preferably provided between the voltage-current converter circuit 103 and the interpolation circuit 104, where the difference in voltages is large.

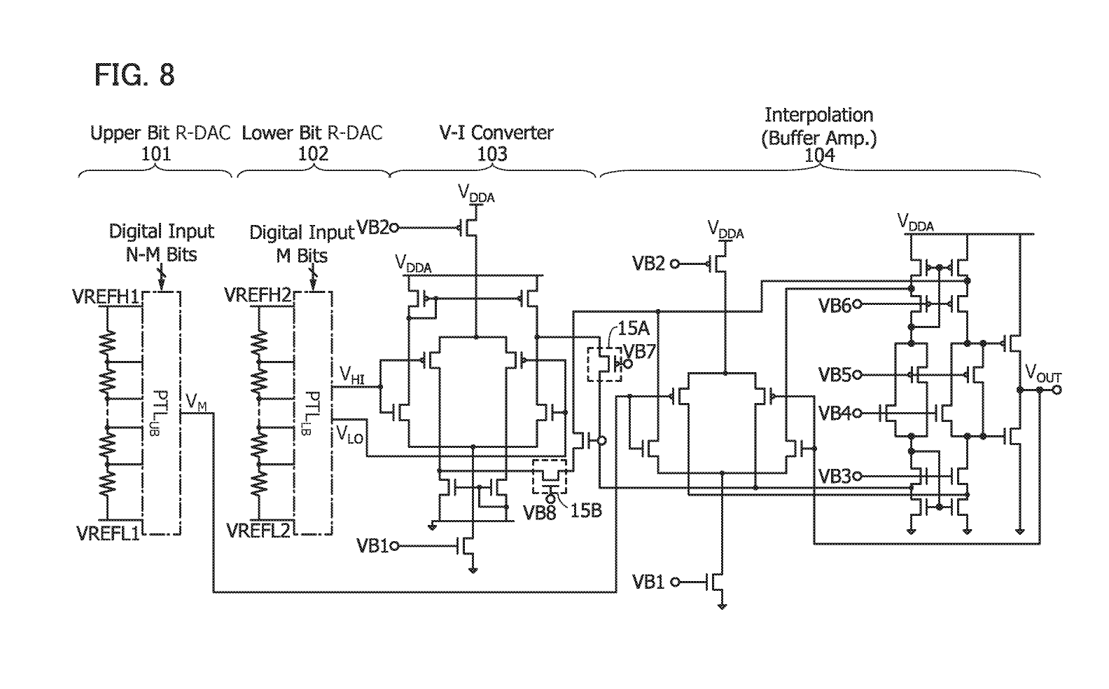

For example, buffer circuits 15A and 15B are provided as illustrated in FIG. 7. As illustrated in FIG. 8, a p-channel transistor supplied with a bias voltage VB7 can be provided as the buffer circuit 15A and an n-channel transistor supplied with a bias voltage VB8 can be provided as the buffer circuit 15B.

### Summary

As has been described, the semiconductor device 100 of this embodiment separately produces an upper-bit grayscale voltage and a lower-bit grayscale voltage and then converts the grayscale voltages into currents and synthesizes the currents. Then, the obtained current is converted into a voltage, and thus an intended grayscale voltage is obtained. The upper-bit grayscale voltage and the lower-bit grayscale voltage are generated using the respective D/A converter circuits each including a resistor string circuit and a pass transistor logic.

This structure prevents the increase in the number of transistors supplied with high voltage, which occurs along with the increase in the number of bits of digital signals; thus, D/A conversion of multi-bit digital signals can be performed. Consequently, the increase in parasitic capacitance can be suppressed, and a smaller circuit area and higher response speed are obtained.

### Embodiment 2

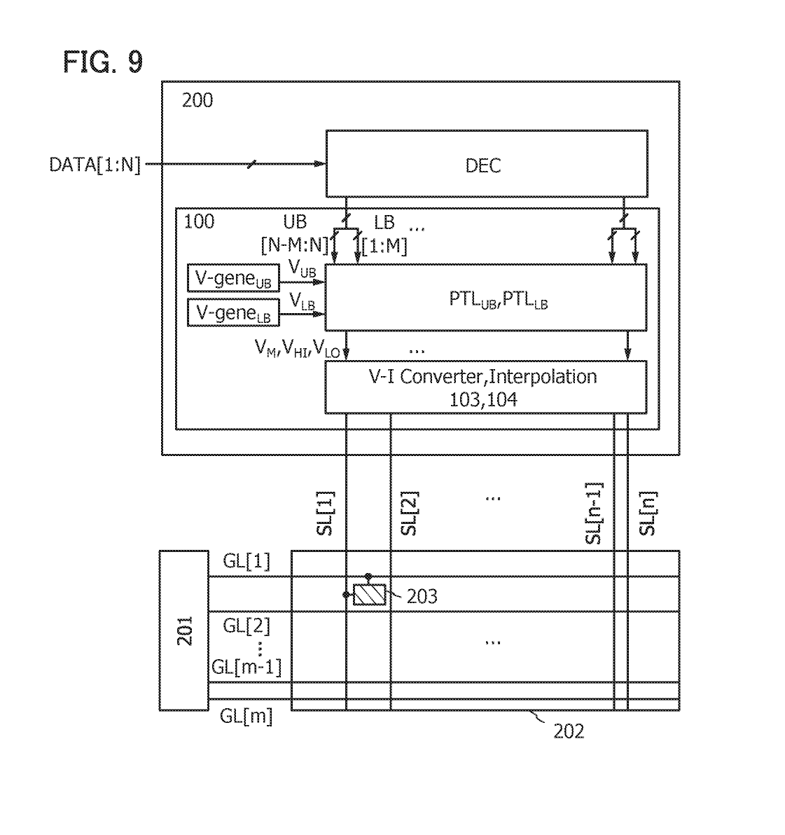

This embodiment will explain a circuit block diagram of a display device including the semiconductor device described in Embodiment 1, which functions as a grayscale voltage generator circuit. FIG. 9 is a circuit block diagram illustrating a source driver, a gate driver, and a display portion.

The display device in the circuit block diagram of FIG. 9 includes a source driver 200, a gate driver 201, and a display portion 202. In FIG. 9, a pixel 203 is shown in the display portion 202.

Digital signals DATA[1] to DATA[N] (DATA[1:N] in FIG. 9) are input to a decoder DEC. The decoder DEC outputs a digital signal to the semiconductor device 100.

The source driver 200 can include the semiconductor device described in Embodiment 1. Specifically, the source driver 200 includes the decoder DEC and the semiconductor device 100. The semiconductor device 100 includes the voltage generator circuit 112, the voltage generator circuit 122, the pass transistor logic 111, the pass transistor logic 121, the voltage-current converter circuit 103, and the interpolation circuit 104 as described in Embodiment 1. The source driver 200 has a function of outputting an analog signal to source lines SL[1] to SL[n] (n is a natural number of 2 or more).

The semiconductor device 100 is as described in Embodiment 1. In other words, the semiconductor device 100 divides a digital signal into an upper bit and a lower bit and separately generates grayscale voltages (V_{M}, V_{HI}, V_{LO}) on the basis of reference voltages (V_{UB}, V_{LB}), and then converts the grayscale voltages into currents and synthesizes the currents. The obtained current is converted into a voltage, and thus an intended grayscale voltage is obtained. This structure prevents the increase in the number of transistors supplied with high voltage, which occurs along with the increase in the number of bits of digital signals. Thus, the increase in parasitic capacitance can be suppressed, and a smaller circuit area and higher response speed are obtained.

The gate driver 201 includes a shift register and a buffer, for example. The gate driver 201 receives a gate start pulse, a gate clock signal, and the like and outputs a pulse signal. A circuit included in the gate driver 201 may be an IC as in the source driver 200 or may be formed using a transistor similar to that in the pixel 203 of the display portion 202.

The gate driver 201 outputs scan signals to gate lines GL[1] to GL[m] (m is a natural number of 2 or more). Note that a plurality of gate drivers 201 may be provided to separately control the gate lines GL[1] to GL[m]. For example, the gate drivers 201 may be provided on the right and left of the display portion 202 and separately control the gate lines GL[1] to GL[m] on a row-by-row basis.

In the display portion 202, the gate lines GL[1] to GL[m] and the source lines SL[1] to SL[n] are provided to intersect at substantially right angles. The pixel 203 is provided at the intersection of the gate line and the source line. For color display, the pixels 203 corresponding to the respective colors of red, green, and blue (RGB) are arranged in sequence in the display portion 202. Note that the pixels of RGB can be arranged in a stripe pattern, a mosaic pattern, a delta pattern, or the like as appropriate. Without limitation to RGB, a pixel corresponding to white, yellow, or the like may be added for color display.

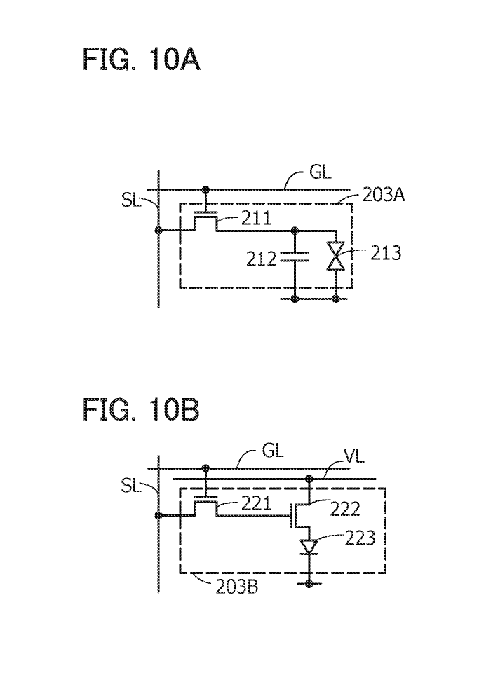

FIGS. 10A and 10B illustrate configuration examples of the pixel 203.

A pixel 203A in FIG. 10A is an example of a pixel included in a liquid crystal display device and includes a transistor 211, a capacitor 212, and a liquid crystal element 213.

The transistor 211 serves as a switching element for controlling the connection between the liquid crystal element 213 and the source line SL. The on/off state of the transistor 211 is controlled by a scan signal input to its gate through the gate line GL.

The capacitor 212 is, for example, an element formed by sandwiching an insulating layer between conductive layers.

The liquid crystal element 213 includes a common electrode, a pixel electrode, and a liquid crystal layer, for example. Alignment of the liquid crystal material of the liquid crystal layer is changed by the action of an electric field generated between the common electrode and the pixel electrode.

A pixel 203B in FIG. 10B is an example of a pixel included in an EL display device and includes a transistor 221, a transistor 222, and an EL element 223. FIG. 10B illustrates a power supply line VL in addition to the gate line GL and the source line SL. The power supply line VL is a wiring for supplying current to the EL element 223.

The transistor 221 serves as a switching element for controlling the connection between a gate of the transistor 222 and the source line SL. The on/off state of the transistor 221 is controlled by a scan signal input to its gate through the gate line GL.

The transistor 222 has a function of controlling current flowing between the power supply line VL and the EL element 223, in accordance with voltage applied to the gate of the transistor 222.

The EL element 223 is, for example, an element including a light-emitting layer provided between electrodes. The luminance of the EL element 223 can be controlled by the amount of current that flows through the light-emitting layer.

The display device in the above circuit block diagram includes the semiconductor device 100 described in Embodiment 1, resulting in preventing the increase in the number of transistors supplied with high voltage, which occurs along with the increase in the number of bits of digital signals. As a result, it is possible to suppress the increase in parasitic capacitance, reduce the circuit area, and increase the response speed.

### Embodiment 3

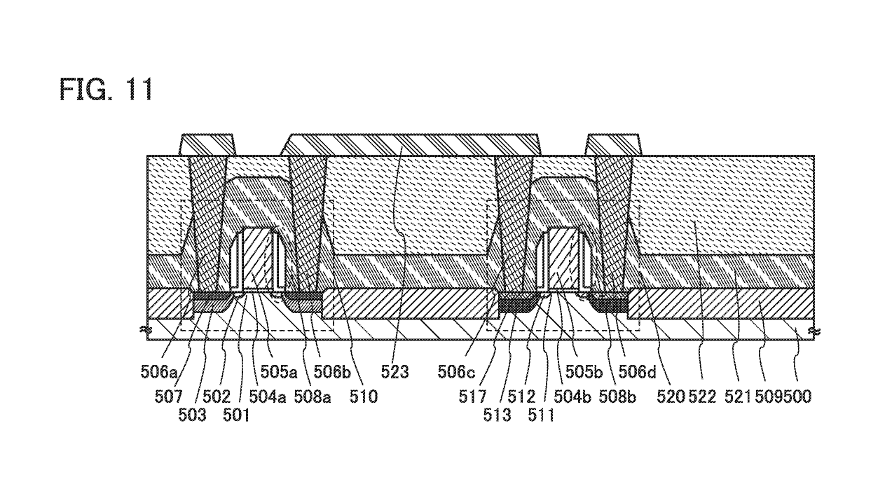

In this embodiment, an example of a cross-sectional structure of a semiconductor device in one embodiment of the present invention will be described with reference FIG. 11.

In the semiconductor device shown in Embodiment 1, the D/A converter circuit 101, the D/A converter circuit 102, the voltage-current converter circuit 103, and the interpolation circuit 104 are formed using transistors containing silicon or the like. As silicon, polycrystalline silicon, microcrystalline silicon, or amorphous silicon can be used. Note that an oxide semiconductor or the like can be used instead of silicon.

FIG. 11 is a schematic cross-sectional view of a semiconductor device of one embodiment of the present invention. The semiconductor device in the schematic cross-sectional view of FIG. 11 includes an n-channel transistor and a p-channel transistor that contain a semiconductor material (e.g., silicon).

An n-channel transistor 510 includes a channel formation region 501 in a substrate 500 containing a semiconductor material, low-concentration impurity regions 502 and high-concentration impurity regions 503 (collectively referred to simply as impurity regions in some cases) with the channel formation region 501 placed between the impurity regions, intermetallic compound regions 507 in contact with the impurity regions, a gate insulating film 504a over the channel formation region 501, a gate electrode layer 505a over the gate insulating film 504a, and a source electrode layer 506a and a drain electrode layer 506b in contact with the intermetallic compound regions 507. A sidewall insulating film 508a is provided on a side surface of the gate electrode layer 505a. An interlayer insulating film 521 and an interlayer insulating film 522 are provided to cover the transistor 510. The source electrode layer 506a and the drain electrode layer 506b are connected to the intermetallic compound regions 507 through openings formed in the interlayer insulating films 521 and 522.

A p-channel transistor 520 includes a channel formation region 511 in the substrate 500 containing the semiconductor material, low-concentration impurity regions 512 and high-concentration impurity regions 513 (collectively referred to simply as impurity regions in some cases) with the channel formation region 511 placed between the impurity regions, intermetallic compound regions 517 in contact with the impurity regions, a gate insulating film 504b over the channel formation region 511, a gate electrode layer 505b over the gate insulating film 504b, and a source electrode layer 506c and a drain electrode layer 506d in contact with the intermetallic compound regions 517. A sidewall insulating film 508b is provided on a side surface of the gate electrode layer 505b. The interlayer insulating films 521 and 522 are provided to cover the transistor 520. The source electrode layer 506c and the drain electrode layer 506d are connected to the intermetallic compound regions 517 through openings formed in the interlayer insulating films 521 and 522.

An element isolation insulating film 509 is provided in the substrate 500 to surround the transistors 510 and 520.

Although FIG. 11 shows the case where the channels of the transistors 510 and 520 are formed in the semiconductor substrate, the channels of the transistors 510 and 520 may be formed in an amorphous semiconductor film or a polycrystalline semiconductor film formed over an insulating surface. Alternatively, the channels of the transistors may be formed in a single crystal semiconductor film, as in the case of using an SOI substrate.

When the transistors 510 and 520 are formed using a single crystal semiconductor substrate, the transistors 510 and 520 can operate at high speed. Accordingly, a single crystal semiconductor substrate is preferably used for transistors that form a switch, a transconductance amplifier, a buffer amplifier, and the like in the semiconductor device of Embodiment 1.

The transistor 510 is connected to the transistor 520 through a wiring 523. It is possible to employ a structure where an interlayer insulating film and an electrode layer are provided over the wiring 523 and another transistor is stacked over them.

### Embodiment 4

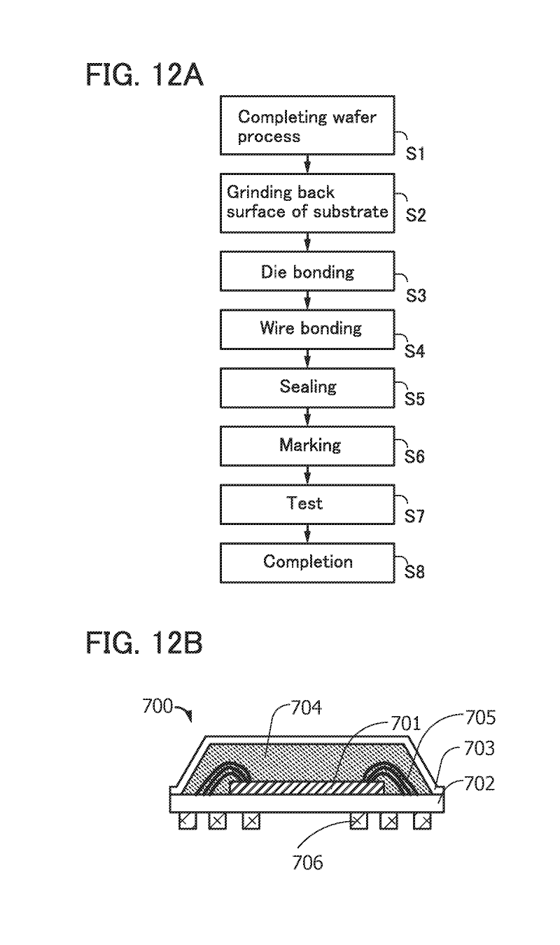

In this embodiment, an application example of the semiconductor device described in the foregoing embodiments to an electronic component, application examples of the electronic component to a display module, an application example of the display module, and application examples of an electronic device will be described with reference to FIGS. 12A and 12B, FIGS. 13A and 13B, FIG. 14, and FIGS. 15A to 15E.

### Application Example to Electronic Component

FIG. 12A shows an example where the semiconductor device described in the foregoing embodiment is used to make an electronic component. Note that an electronic component is also referred to as semiconductor package or IC package. For the electronic component, there are various standards and names corresponding to the direction or the shape of terminals; hence, one example of the electronic component will be described in this embodiment.

A semiconductor device including the transistors illustrated in FIG. 11 of Embodiment 3 is completed by integrating detachable components on a printed circuit board through the assembly process (post-process).

The post-process can be completed through steps shown in FIG. 12A. Specifically, after an element substrate obtained in the wafer process is completed (Step S1), a back surface of the substrate is ground (Step S2). The substrate is thinned in this step to reduce warpage or the like of the substrate in the wafer process and to reduce the size of the component itself.

A dicing step of grinding the back surface of the substrate to separate the substrate into a plurality of chips is performed. Then, a die bonding step of individually picking up separate chips to be mounted on and bonded to an interposer is performed (Step S3). To bond a chip and an interposer in the die bonding step, resin bonding, tape-automated bonding, or the like is selected as determined as appropriate by products.

Next, wire bonding for electrically connecting a wire of the interposer and an electrode on the chip through a metal wire is performed (Step S4). As a metal wire, a silver wire or a gold wire can be used. For wire bonding, ball bonding or wedge bonding can be employed.

The wire-bonded chip is subjected to a molding step of sealing the chip with an epoxy resin or the like (Step S5). With the molding step, the inside of the electronic component is filled with a resin, thereby reducing damage to the circuit portion and the wire embedded in the component caused by external mechanical force as well as reducing deterioration of characteristics due to moisture or dust.

Subsequently, printing process (marking) is performed on a surface of the package (Step S6). Then, through a final test step (Step S7), the electronic component is completed (Step S8).

Since the electronic component described above includes the semiconductor device described in the foregoing embodiment, it is possible to obtain an electronic component with a smaller circuit area and higher response speed.

FIG. 12B is a schematic cross-sectional view of a completed electronic component. In an electronic component 700 illustrated in FIG. 12B, a semiconductor device 701 is provided on a surface of an interposer 702. The semiconductor device 701 is connected to a wiring on the surface of the interposer 702 via a wire 705 to be electrically connected to a bump terminal 706 provided on the back surface of the interposer 702. The semiconductor device 701 over the interposer 702 is sealed by a package 703 with a space between the interposer 702 and the package 703 filled with an epoxy resin 704.

The electronic component 700 in FIG. 12B is mounted on a flexible printed circuit (FPC) or a display panel, for example.

### Examples of Mounting Electronic Component on Display Panel

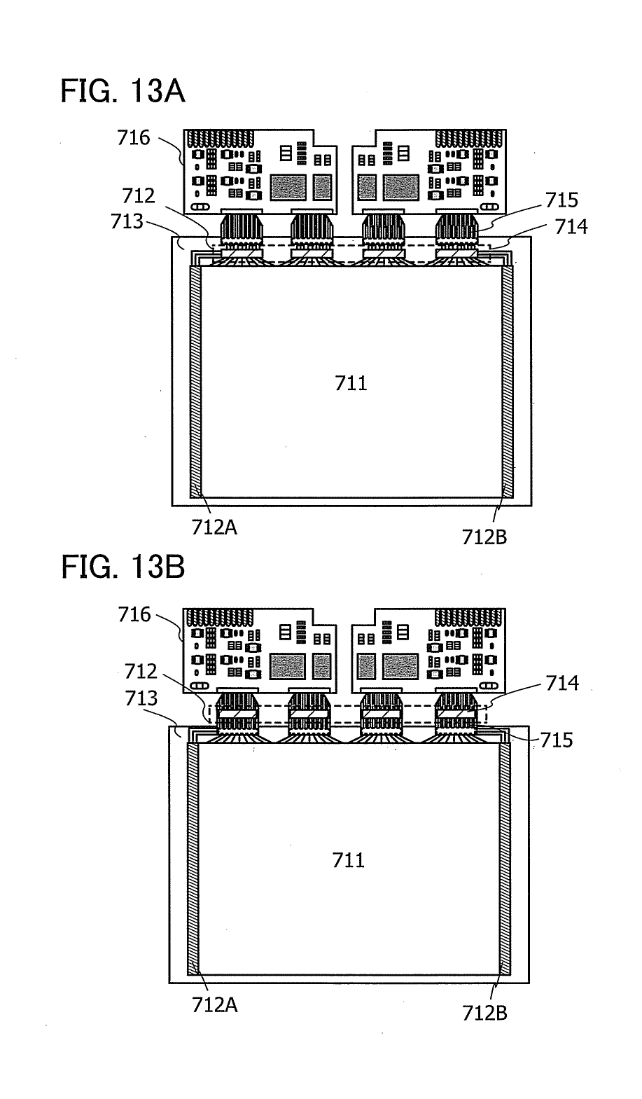

Next, examples of mounting the above electronic component on a display panel will be described with reference to FIGS. 13A and 13B. The electronic component can be used as a source driver IC for the display panel.

FIG. 13A illustrates an example where a source driver 712 and gate drivers 712A and 712B are provided around a display portion 711 and a source driver IC 714 is mounted on a substrate 713 as the source driver 712.

The source driver IC 714 is mounted on a substrate 713 using an anisotropic conductive adhesive and an anisotropic conductive film.

The source driver IC 714 is connected to an external circuit board 716 via an FPC 715.

FIG. 13B illustrates an example where the source driver 712 and the gate drivers 712A and 712B are provided around the display portion 711 and the source driver IC 714 is mounted on the FPC 715 as the source driver 712.

Mounting the source driver IC 714 on the FPC 715 allows a larger display portion 711 to be provided over the substrate 713, resulting in a narrower frame.

### Application Example of Display Module

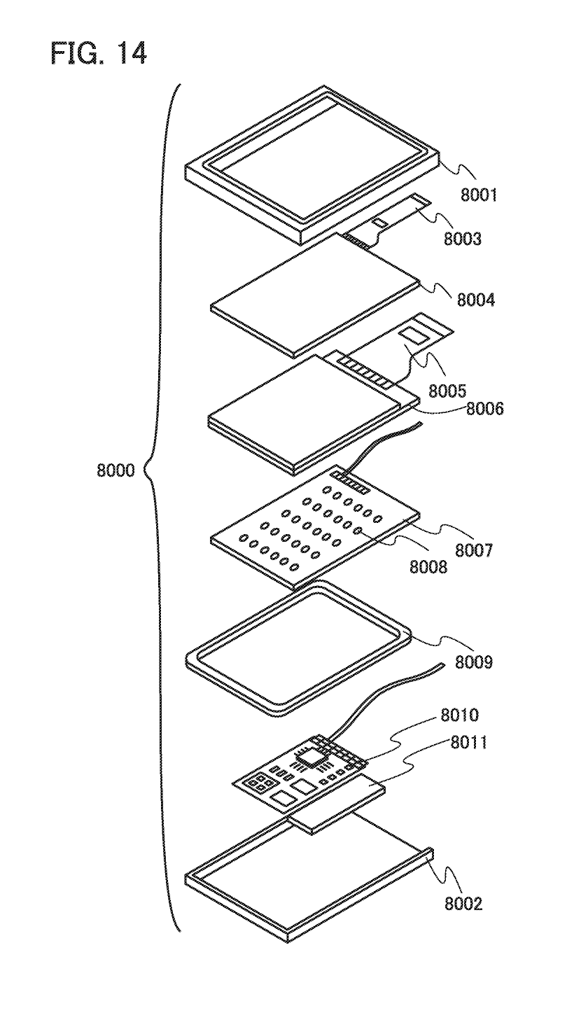

Next, an application example of a display module using the display panel illustrated in FIG. 13A or FIG. 13B will be described with reference to FIG. 14.

In a display module 8000 illustrated in FIG. 14, a touch panel 8004 connected to an FPC 8003, a display panel 8006 connected to an FPC 8005, a backlight unit 8007, a frame 8009, a printed circuit board 8010, and a battery 8011 are provided between an upper cover 8001 and a lower cover 8002. Note that the backlight unit 8007, the battery 8011, the touch panel 8004, and the like are not provided in some cases.

The display panel illustrated in FIG. 13A or FIG. 13B can be used as the display panel 8006 in FIG. 14.

The shape and size of the upper cover 8001 and the lower cover 8002 can be changed as appropriate in accordance with the size of the touch panel 8004 and the display panel 8006.

The touch panel 8004 can be a resistive touch panel or a capacitive touch panel and can be formed to overlap with the display panel 8006. It is also possible to provide a touch panel function for a counter substrate (sealing substrate) of the display panel 8006. Alternatively, a photosensor may be provided in each pixel of the display panel 8006 so that an optical touch panel is obtained. Further alternatively, an electrode for a touch sensor may be provided in each pixel of the display panel 8006 so that a capacitive touch panel is obtained. In such cases, the touch panel 8004 can be omitted.

The backlight unit 8007 includes a light source 8008. The light source 8008 may be provided at an end portion of the backlight unit 8007 and a light diffusing plate may be used.

The frame 8009 protects the display panel 8006 and functions as an electromagnetic shield for blocking electromagnetic waves generated by the operation of the printed circuit board 8010. The frame 8009 may also function as a radiator plate.

The printed circuit board 8010 is provided with a power supply circuit and a signal processing circuit for outputting a video signal and a clock signal. As a power source for supplying power to the power supply circuit, an external commercial power source or a separate power source using the battery 8011 may be used. The battery 8011 can be omitted in the case of using a commercial power source.

The display module 8000 may be additionally provided with a polarizing plate, a retardation plate, a prism sheet, or the like.

### Application Examples of Electronic Component to Electronic Device

Next, an electronic device having a display panel including the above electronic component will be described. Examples of the electronic device include a computer, a portable information appliance (including a mobile phone, a portable game machine, and an audio reproducing device), electronic paper, a television device (also referred to as television or television receiver), and a digital video camera.

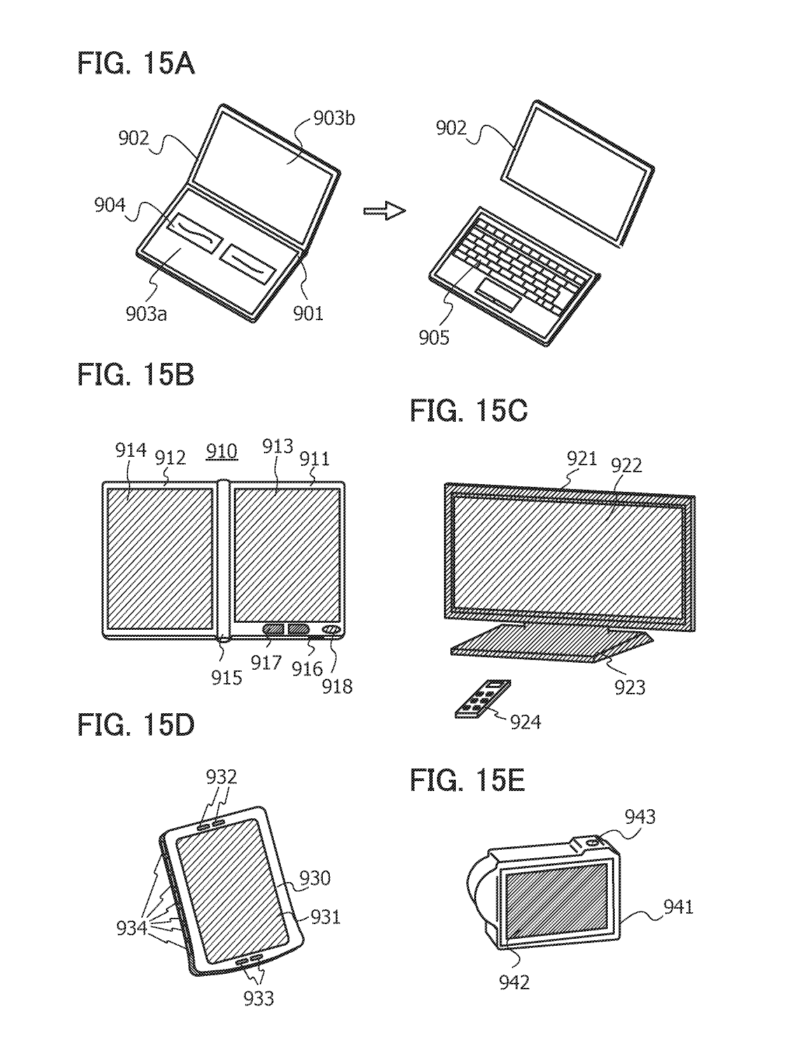

FIG. 15A illustrates a portable information appliance that includes a housing 901, a housing 902, a first display portion 903a, a second display portion 903b, and the like. At least one of the housings 901 and 902 is provided with the electronic component including the semiconductor device of the foregoing embodiment. It is thus possible to obtain a portable information appliance with a smaller circuit area and higher response speed.

The first display portion 903a is a panel having a touch input function, and for example, as illustrated in the left of FIG. 15A, which of “touch input” and “keyboard input” is performed can be selected by a selection button 904 displayed on the first display portion 903a. Since selection buttons with a variety of sizes can be displayed, the information appliance can be easily used by people of any generation. For example, when “keyboard input” is selected, a keyboard 905 is displayed on the first display portion 903a as illustrated in the right of FIG. 15A. Thus, letters can be input quickly by keyboard input as in a conventional information appliance, for example.

One of the first display portion 903a and the second display portion 903b can be detached from the portable information appliance as shown in the right of FIG. 15A. Providing the second display portion 903b with a touch input function makes the information appliance convenient to carry because a weight to carry around can be further reduced and the information appliance can operate with one hand while the other hand supports the housing 902.

The portable information appliance in FIG. 15A can be equipped with a function of displaying a variety of information (e.g., a still image, a moving image, and a text image); a function of displaying a calendar, a date, the time, or the like on the display portion; a function of operating or editing information displayed on the display portion; a function of controlling processing by various kinds of software (programs); and the like. Furthermore, an external connection terminal (e.g., an earphone terminal or a USB terminal), a recording medium insertion portion, and the like may be provided on the back surface or the side surface of the housing.

The portable information appliance illustrated in FIG. 15A may transmit and receive data wirelessly. Through wireless communication, desired book data or the like can be purchased and downloaded from an e-book server.

Furthermore, the housing 902 in FIG. 15A may be equipped with an antenna, a microphone function, and a wireless communication function to be used as a mobile phone.

FIG. 15B illustrates an e-book reader 910 including electronic paper. The e-book reader 910 has two housings 911 and 912. The housing 911 and the housing 912 are provided with a display portion 913 and a display portion 914, respectively. The housings 911 and 912 are connected by a hinge 915 and can be opened and closed with the hinge 915 as an axis. The housing 911 is provided with a power switch 916, an operation key 917, a speaker 918, and the like. The electronic component including the semiconductor device of the foregoing embodiment is provided in at least one of the housings 911 and 912. It is thus possible to obtain an e-book reader with a smaller circuit area and higher response speed.

FIG. 15C illustrates a television device including a housing 921, a display portion 922, a stand 923, and the like. The television device can be controlled by a switch of the housing 921 and a remote controller 924. The electronic component including the semiconductor device of the foregoing embodiment is mounted on the housing 921 and the remote controller 924. Thus, it is possible to obtain a television device with a smaller circuit area and higher response speed.

FIG. 15D illustrates a smartphone in which a main body 930 is provided with a display portion 931, a speaker 932, a microphone 933, an operation button 934, and the like. The electronic component including the semiconductor device of the foregoing embodiment is provided in the main body 930. It is thus possible to obtain a smartphone with a smaller circuit area and higher response speed.

FIG. 15E illustrates a digital camera including a main body 941, a display portion 942, an operation switch 943, and the like. The electronic component including the semiconductor device of the foregoing embodiment is provided in the main body 941. Consequently, it is possible to obtain a digital camera with a smaller circuit area and higher response speed.

As described above, the electronic component including the semiconductor device of the foregoing embodiment is provided in the electronic device shown in this embodiment, thereby decreasing the circuit area and increasing the response speed.

(Supplementary Notes on Description in this Specification and the Like)

The following are notes on the description of Embodiments 1 to 4 and the structures in Embodiments 1 to 4.

### Notes on One Embodiment of the Present Invention Described in Embodiments

One embodiment of the present invention can be constituted by appropriately combining the structure described in an embodiment with any of the structures described in the other embodiments. In addition, in the case where a plurality of structure examples are described in one embodiment, any of the structure examples can be combined as appropriate.

Note that a content (or part thereof) described in one embodiment can be applied to, combined with, or replaced with another content (or part thereof) described in the same embodiment and/or a content (or part thereof) described in another embodiment or other embodiments.

Note that in each embodiment, a content described in the embodiment is a content described with reference to a variety of diagrams or a content described with a text in this specification.

By combining a diagram (or part thereof) described in one embodiment with another part of the diagram, a different diagram (or part thereof) described in the embodiment, and/or a diagram (or part thereof) described in another embodiment or other embodiments, much more diagrams can be created.

One embodiment of the present invention is not limited to those described in Embodiments 1 to 4. For example, in Embodiment 1, a structure using an R-DAC is described as one embodiment of the present invention; however, one embodiment of the present invention is not limited to this. A structure using a DAC other than an R-DAC, for instance, may be one embodiment of the present invention under some circumstances.

### Notes on Description for Drawings

In this specification and the like, terms for describing arrangement, such as “over” and “under”, are used for convenience to indicate a positional relation between components with reference to drawings. The positional relation between components is changed as appropriate in accordance with a direction in which the components are described. Therefore, the terms for explaining arrangement are not limited to those used in this specification and may be changed to other terms as appropriate depending on the situation.

The term “over” or “below” does not necessarily mean that a component is placed directly on or directly below and directly in contact with another component. For example, the expression “electrode B over insulating layer A” does not necessarily mean that the electrode B is on and in direct contact with the insulating layer A and can also mean the case where another component is provided between the insulating layer A and the electrode B.

Furthermore, in a block diagram in this specification and the like, components are functionally classified and shown by blocks that are independent from each other. However, in an actual circuit and the like, such components are sometimes hard to classify functionally, and there is a case where one circuit is associated with a plurality of functions or a case where a plurality of circuits are associated with one function. Therefore, the segmentation of blocks in a block diagram is not limited by any of the components described in the specification and can be differently determined as appropriate depending on the situation.

In the drawings, the size, the layer thickness, or the region is determined arbitrarily for description convenience; therefore, embodiments of the present invention are not limited to such a scale. Note that the drawings are schematically shown for clarity, and embodiments of the present invention are not limited to shapes or values shown in the drawings. For example, the following can be included: variation in signal, voltage, or current due to noise or difference in timing.

### Notes on Expressions that can be Rephrased

In this specification and the like, the terms “one of a source and a drain” (or first electrode or first terminal) and “the other of the source and the drain” (or second electrode or second terminal) are used to describe the connection relation of a transistor. This is because the source and the drain of a transistor are interchangeable depending on the structure, operation conditions, or the like of the transistor. Note that the source or the drain of the transistor can also be referred to as a source (or drain) terminal, a source (or drain) electrode, or the like as appropriate depending on the situation.

In addition, in this specification and the like, the term such as “electrode” or “wiring” does not limit a function of a component. For example, an “electrode” is used as part of a “wiring” in some cases, and vice versa. Moreover, the term “electrode” or “wiring” can also mean a combination of a plurality of electrodes or wirings formed in an integrated manner.

In this specification and the like, “voltage” and “potential” can be replaced with each other. The term “voltage” refers to a potential difference from a reference potential. When the reference potential is a ground voltage, for example, “voltage” can be replaced with “potential.” A ground potential does not necessarily mean 0 V. Potentials are relative values, and a potential supplied to a wiring or the like is sometimes changed depending on the reference potential.

In this specification and the like, the terms “film” and “layer” can be interchanged with each other depending on the case or circumstances. For example, the term “conductive layer” can be changed into the term “conductive film” in some cases. Moreover, the term “insulating film” can be changed into the term “insulating layer” in some cases.

This specification and the like show a 1T-1C circuit structure where one pixel has one transistor and one capacitor and a 2T-1C circuit structure where one pixel has two transistors and one capacitor; however, this specification and the like are not limited to these. It is possible to employ a circuit structure where one pixel has three or more transistors and two or more capacitors. Moreover, a variety of circuit structures can be obtained by formation of an additional wiring.

### Notes on Definitions of Terms

The following are definitions of the terms that are not mentioned in the above embodiments.

### <<Switch>>

In this specification and the like, a switch is conducting or not conducting (is turned on or off) to determine whether current flows therethrough or not. Alternatively, a switch has a function of selecting and changing a current path.

For example, an electrical switch or a mechanical switch can be used. That is, any element can be used as a switch as long as it can control current, without limitation to a certain element.

Examples of an electrical switch include a transistor (e.g., a bipolar transistor and a MOS transistor), a diode (e.g., a PN diode, a PIN diode, a Schottky diode, a metal-insulator-metal (MIM) diode, a metal-insulator-semiconductor (MIS) diode, and a diode-connected transistor), and a logic circuit in which such elements are combined.

In the case of using a transistor as a switch, the “on state” of the transistor refers to a state in which a source and a drain of the transistor are regarded as being electrically short-circuited. The “off state” of the transistor refers to a state in which the source and the drain of the transistor are regarded as being electrically disconnected. In the case where a transistor operates just as a switch, there is no particular limitation on the polarity (conductivity type) of the transistor.

An example of a mechanical switch is a switch formed using a microelectromechanical system (MEMS) technology, such as a digital micromirror device (DMD). Such a switch includes an electrode that can be moved mechanically, and its conduction and non-conduction is controlled with movement of the electrode.

### <<Channel Length>>

In this specification and the like, the channel length refers to, for example, a distance between a source and a drain in a region where a semiconductor (or a portion where a current flows in a semiconductor when a transistor is on) and a gate overlap with each other or a region where a channel is formed in a top view of the transistor.

In one transistor, channel lengths in all regions are not necessarily the same. That is, the channel length of one transistor is not limited to one value in some cases. Therefore, in this specification, the channel length is any one of values, the maximum value, the minimum value, or the average value in a region where a channel is formed.

### <<Channel Width>>

In this specification and the like, the channel width refers to, for example, the length of a portion where a source and a drain face each other in a region where a semiconductor (or a portion where a current flows in a semiconductor when a transistor is on) and a gate overlap with each other, or a region where a channel is formed.

In one transistor, channel widths in all regions are not necessarily the same. That is, the channel width of one transistor is not limited to one value in some cases. Therefore, in this specification, a channel width is any one of values, the maximum value, the minimum value, or the average value in a region where a channel is formed.

Note that in some transistor structures, a channel width in a region where a channel is actually formed (hereinafter referred to as effective channel width) is different from a channel width shown in a top view of a transistor (hereinafter referred to as apparent channel width). For example, in a transistor having a three-dimensional structure, an effective channel width is larger than an apparent channel width shown in a top view of the transistor, and its influence cannot be ignored in some cases. For example, in a miniaturized transistor having a three-dimensional structure, the proportion of a channel region formed on a side surface of a semiconductor is sometimes high. In that case, an effective channel width obtained when a channel is actually formed is larger than an apparent channel width shown in the top view.

In a transistor having a three-dimensional structure, an effective channel width is difficult to measure in some cases. For example, estimation of an effective channel width from a design value requires an assumption that the shape of a semiconductor is known. Thus, in the case where the shape of a semiconductor is not known accurately, it is difficult to measure an effective channel width accurately.

In view of this, in this specification, in a top view of a transistor, an apparent channel width, which is the length of a portion where a source and a drain face each other in a region where a semiconductor and a gate electrode overlap with each other, is sometimes referred to as a surrounded channel width (SCW). Furthermore, in this specification, the term “channel width” may denote a surrounded channel width or an apparent channel width, or may denote an effective channel width. Note that the values of a channel length, a channel width, an effective channel width, an apparent channel width, a surrounded channel width, and the like can be determined by obtaining and analyzing a cross-sectional TEM image and the like.

Note that in the case where electric field mobility, a current value per channel width, and the like of a transistor are obtained by calculation, a surrounded channel width may be used for the calculation. In that case, a value different from one when an effective channel width is used for the calculation is obtained in some cases.

### <<Pixel>>

In this specification and the like, one pixel refers to one element whose brightness can be controlled, for example. Therefore, for example, one pixel corresponds to one color element by which brightness is expressed. Accordingly, in a color display device using color elements of red (R), green (G), and blue (B), the smallest unit of an image is formed of three pixels of an R pixel, a G pixel, and a B pixel.

Note that the number of colors for color elements is not limited to three, and more colors may be used. For example, RGBW (W: white) or RGB added with yellow, cyan, or magenta may be employed.

### <<Display Element>>

In this specification and the like, a display element includes a display medium whose contrast, luminance, reflectivity, transmittance, or the like is changed by electrical or magnetic effect. Examples of the display element include an electroluminescent (EL) element, an LED (e.g., a white LED, a red LED, a green LED, and a blue LED), a transistor (a transistor that emits light depending on current), an electron emitter, a liquid crystal element, electronic ink, an electrophoretic element, a grating light valve (GLV), a plasma display panel (PDP), a display element using microelectromechanical system (MEMS), a digital micromirror device (DMD), a digital micro shutter (DMS), Mirasol (registered trademark), an interferometric modulator display (IMOD) element, a MEMS shutter display element, an optical-interference-type MEMS display element, an electrowetting element, a piezoelectric ceramic display, and a display element using a carbon nanotube.

### <<Connection>>

In this specification and the like, when it is described that “A and B are connected to each other”, the case where A and B are electrically connected to each other is included in addition to the case where A and B are directly connected to each other. Here, the expression “A and B are electrically connected” means the case where electric signals can be transmitted and received between A and B when an object having any electric action exists between A and B.

For example, any of the following expressions can be used for the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y.

Examples of the expressions include “X, Y, and a source (or a first terminal or the like) and a drain (or a second terminal or the like) of a transistor are electrically connected to each other, and X, the source (or the first terminal or the like) of the transistor, the drain (or the second terminal or the like) of the transistor, and Y are electrically connected to each other in this order,” “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order,” and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order.” When the connection order in a circuit configuration is defined by an expression similar to the above examples, a source (or a first terminal or the like) and a drain (or a second terminal or the like) of a transistor can be distinguished from each other to specify the technical scope.

Other examples of the expressions include “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path,” and “a source (or a first terminal or the like) of a transistor is electrically connected to X through Z1 at least with a first connection path, the first connection path does not include a second connection path, the second connection path includes a connection path through the transistor, a drain (or a second terminal or the like) of the transistor is electrically connected to Y through Z2 at least with a third connection path, and the third connection path does not include the second connection path.” Still another example of the expression is “a source (or a first terminal or the like) of a transistor is electrically connected to X through Z1 on at least a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through Z2 on at least a third electrical path, the third electrical path does not include a fourth electrical path, and the fourth electrical path is an electrical path from the drain (or the second terminal or the like) of the transistor to the source (or the first terminal or the like) of the transistor.” When the connection path in a circuit configuration is defined by an expression similar to the above examples, a source (or a first terminal or the like) and a drain (or a second terminal or the like) of a transistor can be distinguished from each other to specify the technical scope.

Note that these expressions are examples and there is no limitation on the expressions. Here, X, Y, Z1, and Z2 each denote an object (e.g., a device, an element, a circuit, a wiring, an electrode, a terminal, a conductive film, or a layer).

This application is based on Japanese Patent Application serial no. 2015-028351 filed with Japan Patent Office on Feb. 17, 2015, the entire contents of which are hereby incorporated by reference.

What is claimed is:

1. A semiconductor device comprising:
a first digital-to-analog converter circuit;
a second digital-to-analog converter circuit;
an interpolation circuit; and
a voltage-current converter circuit,
wherein the first digital-to-analog converter circuit is configured to convert an upper (N-M)-bit digital signal among an N-bit digital signal into a first voltage, where N is a natural number of 2 or more and M is a natural number less than N,
wherein the second digital-to-analog converter circuit is configured to convert a lower M-bit digital signal into a second voltage,
wherein the interpolation circuit is configured to generate a first current on the basis of the first voltage,
wherein the voltage-current converter circuit is configured to convert the second voltage into a second current, and
wherein the interpolation circuit is configured to convert a current obtained by synthesis of the first current and the second current, into a voltage.

2. The semiconductor device according to claim 1,
wherein the first digital-to-analog converter circuit comprises a first resistor string circuit and a plurality of first switches, and
wherein the second digital-to-analog converter circuit comprises a second resistor string circuit and a plurality of second switches.

3. The semiconductor device according to claim 1, wherein the voltage-current converter circuit is a transconductance amplifier.

4. The semiconductor device according to claim 1, wherein the interpolation circuit is a buffer amplifier.

5. An electronic component comprising:
the semiconductor device according to claim 1; and
a bump terminal electrically connected to the semiconductor device.

6. An electronic device comprising:
the electronic component according to claim 5; and
a display device.

7. A semiconductor device comprising:
a first digital-to-analog converter circuit;
a second digital-to-analog converter circuit;
an interpolation circuit;
a voltage-current converter circuit; and
a buffer circuit,
wherein the first digital-to-analog converter circuit is configured to convert an upper (N-M)-bit digital signal among an N-bit digital signal into a first voltage, where N is a natural number of 2 or more and M is a natural number less than N,
wherein the second digital-to-analog converter circuit is configured to convert a lower M-bit digital signal into a second voltage,
wherein the interpolation circuit is configured to generate a first current on the basis of the first voltage,
wherein the voltage-current converter circuit is configured to convert the second voltage into a second current,
wherein the interpolation circuit is configured to convert a current obtained by synthesis of the first current and the second current, into a voltage, and
wherein the interpolation circuit is electrically connected to the voltage-current converter circuit via the buffer circuit.

8. The semiconductor device according to claim 7,
wherein the first digital-to-analog converter circuit comprises a first resistor string circuit and a plurality of first switches, and
wherein the second digital-to-analog converter circuit comprises a second resistor string circuit and a plurality of second switches.

9. The semiconductor device according to claim 7, wherein the voltage-current converter circuit is a transconductance amplifier.

10. The semiconductor device according to claim 7, wherein the interpolation circuit is a buffer amplifier.

11. An electronic component comprising:
the semiconductor device according to claim 7; and
a bump terminal electrically connected to the semiconductor device.

12. An electronic device comprising:
the electronic component according to claim 11; and
a display device.
